(19) United States
(12) Patent Application Publication
(10) Pub. No.: US 2026/0198304 A1
(43) Pub. Date: Jul. 9, 2026

(54) INTEGRATED CIRCUIT

(71) Applicant: Samsung Electronics Co., Ltd., Suwon-si (KR)

(72) Inventors: Hankyung Kim, Suwon-si (KR); Seungkwon Lee, Suwon-si (KR); Hana Kim, Suwon-si (KR); Jiyoon Hong, Suwon-si (KR)

(21) Appl. No.: 19/432,456

(22) Filed: Dec. 24, 2025

(30) Foreign Application Priority Data
Jan. 8, 2025 (KR) 10-2025-0002882

(51) Int. Cl. H10W 20/40; H10D 1/00; H10D 1/66; H10W 20/41; H10W 20/42; H10W 20/43

(52) U.S. Cl. CPC H10W 20/496; H10D 1/66; H10W 20/422; H10W 20/43; H10W 20/435; H10D 1/047

(57) ABSTRACT

An integrated circuit includes a first decoupling capacitor cell having a first discharge path and a second decoupling capacitor cell having a second discharge path, where the first discharge path is formed at an external region of the first decoupling capacitor cell, and the second discharge path is formed at an internal region of the second decoupling capacitor cell.

### CROSS-REFERENCE TO RELATED APPLICATION

This application is based on and claims priority under 35 USC § 119 to Korean Patent Application No. 10-2025-0002882, filed on Jan. 8, 2025, in the Korean Intellectual Property Office, the disclosure of which is incorporated by reference herein in its entirety.

### BACKGROUND

Semiconductor devices may include circuit blocks that perform logic functions, and the circuit blocks may include unit circuits that perform predetermined functions and a capacitor that supplies a stable power voltage and remove noise. The capacitor may be, for example, a decoupling capacitor.

### SUMMARY

In some examples, the decoupling capacitor may remove high-frequency noise entering the power supply voltage or directly provide the power supply voltage required by internal components when a circuit block operates at high frequency, thereby eliminating an inductance component that may occur when connected to an external power source and lowering impedance from the perspective of power source. Here, it may be desired to remove plasma charges occurring during the operation of a semiconductor device.

The present disclosure provides a cell structure capable of discharging plasma charges in a cell including a decoupling capacitor.

In general, in some aspects, the present disclosure provides an integrated circuit including: first decoupling capacitor cell having a first discharge path that guides discharge of first charged particles; and a second decoupling capacitor cell having a second discharge path that guides discharge of second charged particles, where the first discharge path is in an external region of the first decoupling capacitor cell, and where the second discharge path is in an internal region of the second decoupling capacitor cell.

In general, in some aspects, the present disclosure provides an integrated circuit including a plurality of cell arrays, where the plurality of cell arrays include a first decoupling capacitor cell array including a plurality of first decoupling capacitor cells, and a second decoupling capacitor cell array including a plurality of second decoupling capacitor cells, where each first decoupling capacitor cell of the plurality of first decoupling capacitor cells includes a plurality of top metal lines forming a first path that guides discharge of charged particles, and where each second decoupling capacitor cell of the plurality of second decoupling capacitor cells includes a second junction region that forms a second path that guides discharge of charged particles.

In general, in some aspects, the present disclosure provides an integrated circuit including a plurality of cell arrays; and an input/output (I/O) pad configured to transmit and receive signals to and from the plurality of cell arrays, where the I/O pad includes a first discharge path that guides discharge of charged particles, including plasma charged particles formed by the plurality of cell arrays.

### BRIEF DESCRIPTION OF THE DRAWINGS

FIG. 1 is a diagram illustrating an integrated circuit including a plurality of unit cells.

FIG. 2 is a diagram illustrating a connection relationship between input/output pads and decoupling capacitor cells in an integrated circuit.

FIG. 3 is a plan view illustrating a connection relationship between a first decoupling capacitor cell and an input/output pad.

FIG. 4 is a cross-sectional view taken along line A-A′ of the plan view of FIG. 3.

FIG. 5 is a cross-sectional view taken along line B-B′ of the plan view of FIG. 3.

FIG. 6 is a plan view of a second decoupling capacitor cell.

FIG. 7 is an example of a cross-sectional view taken along line C-C′ of the second decoupling capacitor cell of FIG. 6.

FIG. 8 is another example of a cross-sectional view of a second decoupling capacitor cell.

FIG. 9 is another example of a cross-sectional view of a second decoupling capacitor cell.

FIG. 10 is another example of a cross-sectional view of a first decoupling capacitor cell.

FIGS. 11A to 11D are diagrams illustrating examples of components that may be included in an integrated circuit.

FIG. 12 is a flowchart illustrating a method of manufacturing an integrated circuit.

FIG. 13 is a block diagram illustrating a system-on-chip.

FIG. 14 is a block diagram illustrating a computing system including a memory storing a program.

### DETAILED DESCRIPTION

Hereinafter, various implementations are described with reference to the accompanying drawings.

Herein, the X-axis direction and the Y-axis direction may be referred to as a first direction (or a first horizontal direction) and a second direction (or a second horizontal direction), respectively, and the Z-axis direction may be referred to as a vertical direction or a third direction. A plane formed by the X-axis and the Y-axis may be referred to as a horizontal plane, and a component positioned in a +Z-axis direction relative to other components may be referred to as being located on another component, and a component positioned in a −Z-axis direction relative to other components may be referred to as being located below other components. In addition, the area of a component may refer to the size of the component that occupies in a plane parallel to a horizontal plane, and the width of the component may refer to the length of the component in a direction orthogonal to the direction in which the component extends. A surface exposed in the +Z direction may be referred to as a top surface, a surface exposed in the −Z direction may be referred to as a bottom surface, and a surface exposed in the ±X direction or ±Y direction may be referred to as a side surface. A pattern including a conductive material, such as a pattern of an interconnection layer, may be referred to as a conductive pattern or may simply be referred to as a pattern. In addition, a pattern extending in one direction may be referred to as a line.

In the drawings of this specification, only some layers may be depicted for convenience of illustration, and vias connecting upper and lower patterns may be indicated for understanding even though they are located below the upper pattern.

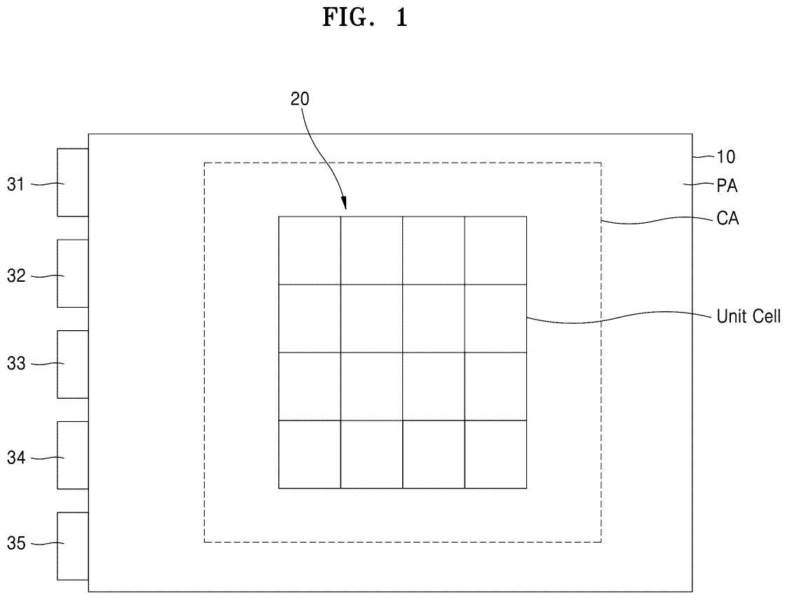

FIG. 1 is a diagram illustrating an integrated circuit 10 including a plurality of unit cells.

Referring to FIG. 1, the integrated circuit 10 may include a cell array region CA in which a plurality of cells are arranged and an external region PA. In some examples, a plurality of metal lines and a plurality of circuit devices connected thereto may be arranged in the cell array region CA. The external region PA may be a peripheral region surrounding the cell array region CA. In some examples, a cell array 20 including a plurality of cells may be arranged in the cell array region CA. The cell array 20 may include a plurality of unit cells. As illustrated in FIG. 1, the cell array 20 includes 4×4 unit cells, but this is shown for illustrative purposes, and the cell array 20 may include tens to hundreds or thousands of unit cells.

Some of the plurality of cells included in the cell array 20 may be standard cells. The standard cell is a unit of layout included in the integrated circuit 10 and may be referred to simply as a cell in this specification. In some examples, the standard cell may be a functional cell or a logic cell providing Boolean logic functionality or storage functionality. For example, the logic cell may be a NAND, AND, NOR, OR, XOR, inverter, adder, flip-flop, or latch. The integrated circuit 10 may include a number of different logic cells. The standard cells may have a structure that conforms to a predefined specification and may be arranged in a plurality of rows.

In some examples, some of the plurality of cells included in the cell array 20 may be decoupling capacitor cells. In some examples, the decoupling capacitor cell may refer to a minimum unit cell that includes at least one decoupling capacitor and includes either a discharge path to the outside or a discharge path to the inside. In some examples the decoupling capacitor cell may refer to a minimum cell unit that may perform the role of removing high-frequency noise entering a power supply voltage, directly providing the power supply voltage required by internal devices when a circuit block operates at high frequency, or eliminating an inductance component occurring when connected to an external power source. In some examples, a decoupling capacitor array including a plurality of decoupling capacitor cells may be arranged in the cell array region CA according to some implementations, thereby maintaining stability of power supply applied to memory cell arrays included in the integrated circuit 10 and preventing abrupt changes in current. In addition, the decoupling capacitor cells may respectively include discharge paths that may discharge plasma charges generated during circuit operation through a junction structure. The discharge path may guide discharge of charged particles. Through this, unnecessary charges may be stably discharged, which has the effect of ensuring the stability of the circuit. Hereinafter, a detailed structure of the decoupling capacitor cells is described.

Referring to FIG. 1, the integrated circuit 10 may include a plurality of input/output (I/O) pads 31, 32, 33, 34, and 35. In some examples, the plurality of I/O pads 31, 32, 33, 34, and 35 may be pads that may transmit signals provided from the outside to internal cells. In some examples, the plurality of I/O pads 31, 32, 33, 34, and 35 may be pads that may transmit signals generated in internal cells to the outside. In some examples, each of the plurality of I/O pads 31, 32, 33, 34, and 35 may include a buffer circuit. Each of the plurality of I/O pads 31, 32, 33, 34, and 35 may be placed in an edge region of the integrated circuit 10, and various circuits included in the integrated circuit 10 may receive power, data, or signals through the plurality of I/O pads 31, 32, 33, 34, and 35. The plurality of I/O pads 31, 32, 33, 34, and 35 according to some examples may be connected to a circuit that supplies power and may transmit power supply voltages VDD and VSS to the cell array 20.

The decoupling capacitor cell according to some implementations may be connected to an I/O pad so that a discharge path may be controlled in the direction of the I/O pad. The decoupling capacitor cell according to some implementations may be connected to a junction inside the decoupling capacitor cell so that a discharge path may be controlled in an inward direction of the capacitor cell. The connection structure of the decoupling capacitor cell is described in detail with reference to the subsequent drawings.

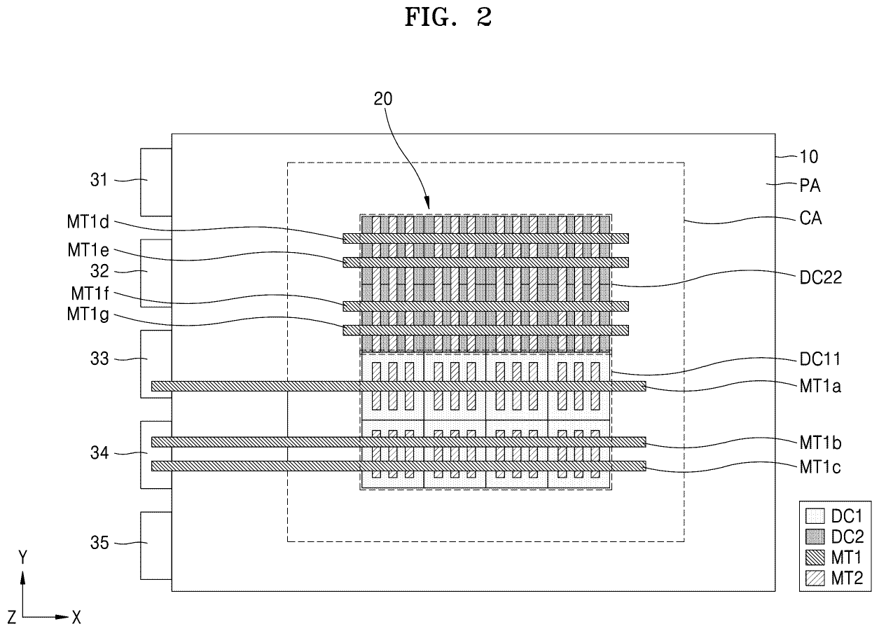

FIG. 2 is a diagram illustrating the connection relationship between I/O pads and decoupling capacitor cells in the integrated circuit 10 according to some implementations.

In the description of FIG. 2, the same descriptions as those given above with reference to FIG. 1 are omitted, and for convenience of description, only some metals are illustrated and vias are omitted.

According to some implementations of FIG. 2, the 4×4 cells included in the cell array 20 may include a plurality of first decoupling capacitor cells DC1 and a plurality of second decoupling capacitor cells DC2. In the description of FIG. 2, the number of first decoupling capacitor cells DC1 is illustrated as being the same as the number of second decoupling capacitor cells DC2, but this is for convenience of description, and the number of first decoupling capacitor cells DC1 and the number of second decoupling capacitor cells DC2 included in the cell array 20 may be variously changed.

In some examples, a first decoupling capacitor cell array DC11 including first decoupling capacitor cells DC1 and a second decoupling capacitor cell array DC22 including second decoupling capacitor cells DC2 are disclosed.

According to some implementations, each of the first decoupling capacitor cell DC1 and the second decoupling capacitor cell DC2 may include first metal lines MT1 and second metal lines MT2. In some examples, the first metal line MT1 may be a metal line formed to extend in the first direction (the X-axis direction), and the second metal line MT2 may be a metal line formed to extend in the second direction (the Y-axis direction). According to some implementations, the first metal line MT1 may be a line disposed above the second metal line MT2. In some examples, the first metal line MT1 may refer to a metal line arranged in the top metal layer in the integrated circuit 10. In some examples, a less number indicated in front of a metal line may indicate a metal line disposed in an upper metal layer. In some implementations, the first metal line MT1 may be a metal line disposed in the top metal layer, and the fifth metal line MT5 may be a metal line disposed in a bottom metal layer.

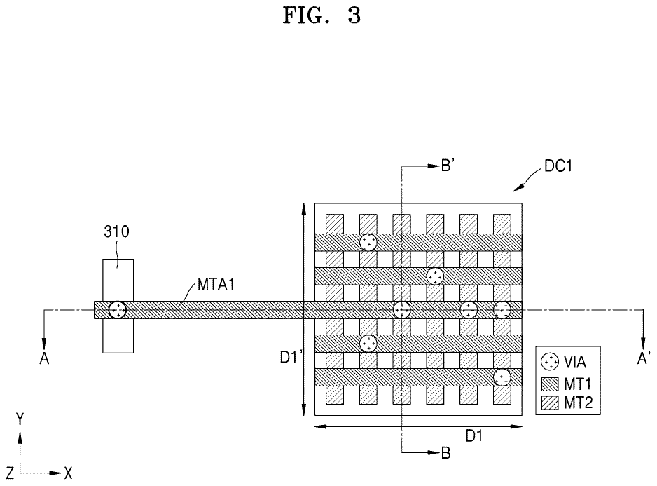

Referring back to FIG. 2, the first metal lines MT1a, MT1b, and MT1c arranged on the top metal layer of the plurality of first decoupling capacitor cells DC1 included in the first decoupling capacitor cell array DC11 may extend to upper regions of some of the I/O pads 33 and 34 among the plurality of I/O pads. The second metal line MT2, excluding the top metal layer of the plurality of first decoupling capacitor cells DC1 included in the first decoupling capacitor cell array DC11, may be provided with a length that is not electrically connected to an adjacent decoupling capacitor cell. Through this structure, the plurality of first decoupling capacitor cells DC1 included in the first decoupling capacitor cell array DC11 may be connected to cells other than the corresponding cell through the first metal lines MT1a, MT1b, and MT1c, which are the top metal lines. The first decoupling capacitor cell array DC11 according to some examples may be connected to the I/O pads 33 and 34 through the first metal lines MT1a, MT1b, and MT1c, and accordingly, plasma charges occurring in the respective first decoupling capacitor cells may be discharged outward in the direction of the I/O pads, thereby forming a first discharge path. This is described in more detail with reference to FIGS. 3 to 5.

Referring to FIG. 2, the first metal lines MT1d, MT1e, MT1f, and MT1g arranged on the top metal layer of the plurality of second decoupling capacitor cells DC2 included in the second decoupling capacitor cell array DC22 may not be connected to the plurality of I/O pads 31, 32, and 33. According to some implementations, the second metal lines MT2 of the plurality of second decoupling capacitor cells DC2 included in the second decoupling capacitor cell array DC22 may extend in the second direction, and the length of the second metal lines MT2 in the second direction may be greater than the length of one second decoupling capacitor cell DC2 in the second direction. That is, the plurality of second decoupling capacitor cells DC2 included in the second decoupling capacitor cell array DC22 may share the second metal lines MT2. Due to this structure, in the second decoupling capacitor cell DC2, the connected metal area may increase, so the influence of plasma charges may be significant. The second decoupling capacitor cell DC2 may discharge the plasma charges in a different manner from that of the first decoupling capacitor cell DC1 by forming a second discharge path inside the second decoupling capacitor cell DC2.

According to some examples, the first decoupling capacitor cell may be distinguished from the second decoupling capacitor cell depending on where a path for discharging plasma charges occurring in the decoupling capacitor cell is formed. In some examples, the first decoupling capacitor cell and the second decoupling capacitor cell may have different structures. In an example, the first decoupling capacitor cell may not include a junction region while the second decoupling capacitor cell may include a junction region. In some examples, the first decoupling capacitor cell and the second decoupling capacitor cell may have different structures in a front-end of line (FEOL) region and a back-end of line (BEOL) region. In an example, the FEOL region of the first decoupling capacitor cell may not include a junction region, while the FEOL region of the second decoupling capacitor cell may include a junction region. In another example, the BEOL region of the first decoupling capacitor cell may include a top metal line connected to an I/O pad, and the BEOL region of the second decoupling capacitor cell may not be connected to the top metal line and an I/O pad. In some examples, the size of the first decoupling capacitor cell may be the same as the size of the second decoupling capacitor cell. Hereinafter, structures of the first decoupling capacitor cell and the second decoupling capacitor cell are described with reference to the drawings.

FIG. 3 is a plan view illustrating a connection relationship between the first decoupling capacitor cell DC1 and I/O pads according to some implementations.

Referring to FIG. 3, the first decoupling capacitor cell DC1 may include a plurality of first metal lines MT1 that extend in the first direction (e.g., the X-axis direction) and are formed apart from each other in the second direction (e.g., the Y-axis direction). The first decoupling capacitor cell DC1 may include second metal lines MT2 that extend in the second direction (e.g., the Y-axis direction) and are formed apart from each other in the first direction (e.g., the X-axis direction). In some examples, the first metal lines MT1 may be arranged on top of the second metal lines MT2. In some examples, the first metal lines MT1 may be metal lines arranged on the top metal layer of the first decoupling capacitor cell DC1.

In some examples, the first decoupling capacitor cell DC1 may further include a via VIA physically connecting the first metal lines MT1 to the second metal lines MT2 in the third direction (e.g., the Z-axis direction).

In some examples, at least one first metal line MTA1 among the first metal lines MT1 included in the first decoupling capacitor cell DC1 may extend in the first direction to have a length that extends beyond the boundary of the first decoupling capacitor cell DC1. The first metal line MTA1 may extend in the first direction and extend to an upper region of a first I/O pad 310. The first metal line MTA1 may be physically connected to the first I/O pad 310 through the via VIA.

Referring to the example of FIG. 3, the first I/O pad 310 and the first decoupling capacitor cell DC1 may share the first metal line MTA and may be physically connected through the first metal line MTA1. Plasma charges occurring in the first decoupling capacitor cell DC1 may move toward the first I/O pad 310 through the first metal line MTA1 and be discharged. The corresponding structure are described in detail with reference to the subsequent drawings.

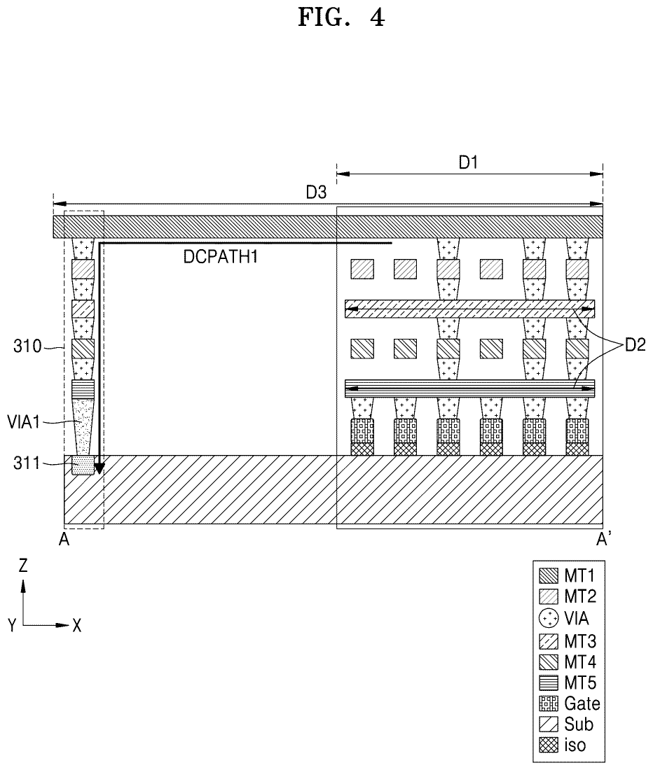

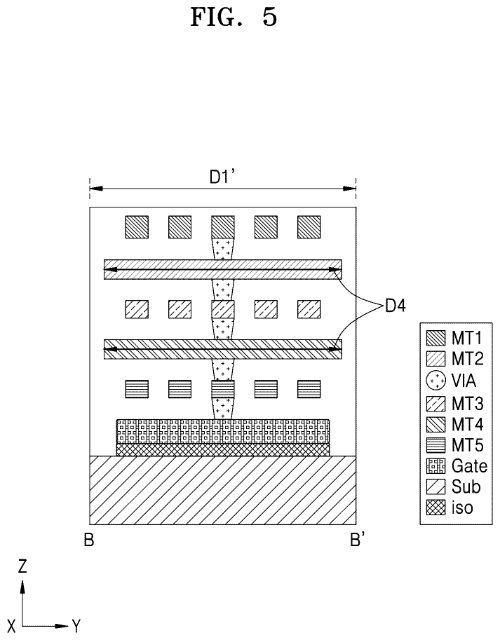

FIG. 4 is a cross-sectional view taken along line A-A′ of the plan view of FIG. 3, and FIG. 5 is a cross-sectional view taken along line B-B′ of the plan view of FIG. 3.

Referring to FIG. 4, the first decoupling capacitor cell DC1 may include a substrate Sub, a plurality of gates Gate, the first metal line MT1, the second metal line MT2, a third metal line MT3, a fourth metal line MT4, and a fifth metal line MT5 and may include a plurality of vias VIA that may physically connect the metal lines to the plurality of gates Gate in the third direction, respectively. In an example, an insulating material Iso may be connected between the plurality of gates Gate and the substrate Sub. Active regions that may be combined with the plurality of gates Gate to form a metal-oxide-semiconductor (MOS) capacitor may be formed on the substrate Sub but are not shown in the cross-sectional views of FIGS. 4 and 5. In some examples, a plurality of MOS capacitors respectively corresponding to the plurality of gates Gate included in the first decoupling capacitor cell DC1 may be formed on the substrate Sub. In some examples, the MOS capacitor may be implemented as either an NFET or a PFET but is not limited thereto.

Referring to FIG. 4, the first metal line MT1, the third metal line MT3, and the fifth metal line MT5 may extend in the first direction. Each of the first metal line MT1, the third metal line MT3, and the fifth metal line MT5 may be arranged apart from each other in the second direction in the metal layer on which each metal line is arranged.

Referring to FIG. 4, the lengths of the third metal line MT3 and the fifth metal line MT5 in the first direction may be different from the length of the first decoupling capacitor cell DC1 in the first direction. A length D2 of the third metal line MT3 and the fifth metal line MT5 in the first direction may be less than a length D1 of the first decoupling capacitor cell DC1 in the first direction. In some examples, the length D2 of the third metal line MT3 and the fifth metal line MT5 in the first direction may be different from a length D3 of the first metal line MT1 in the first direction.

The length D3 of the first metal line MT1 in the first direction may have a value greater than the length D2 of the third metal line MT3 and the fifth metal line MT5 in the first direction and the length D1 of the first decoupling capacitor cell DC1 in the first direction.

Referring to FIG. 4, the length D2 of the other lower metal lines in the first direction, excluding the first metal line MT1, which is the top metal layer, may be less than the length D1 of the first decoupling capacitor cell DC1 in the first direction. Through this, the other metal layers excluding the top metal layer may be provided for routing within the first decoupling capacitor cell DC1 and may not be electrically connected to other external cells.

Referring to FIG. 5, the length of the second metal line MT2 in the second direction and the length of the fourth metal line MT4 in the second direction may be D4. In some examples, the length of the second metal line MT2 in the second direction and the length of the fourth metal line MT4 in the second direction may be different from the length D1′ of the first decoupling capacitor cell DC1 in the second direction. In some examples, the length of the second metal line MT2 in the second direction and the length D4 of the fourth metal line MT4 in the second direction may have values less than the length D1′ of the first decoupling capacitor cell DC1 in the second direction.

Referring to FIGS. 4 and 5, among the plurality of metal lines included in the first decoupling capacitor cell DC1, the lengths of the second metal line MT2, the third metal line MT3, the fourth metal line MT4, and the fifth metal line MT5 arranged in the remaining metal layers, excluding the first metal line MT1 disposed in the top metal layer, may be provided with a length that does not exceed the boundary of the first decoupling capacitor cell DC1. In some examples, the length D1 of the first decoupling capacitor cell DC1 in the first direction may be greater than the length D2 in the first direction of the third metal line MT3 and the fifth metal line MT5 extending in the first direction, and the length D1′ of the first decoupling capacitor cell DC1 in the second direction may be greater than the lengths D4 in the second direction of the second metal line MT2 and the fourth metal line MT4 extending in the second direction. Through this, the remaining metal lines excluding the first metal line MT1 may be used only for routing within the first decoupling capacitor cell DC1.

In the first decoupling capacitor cell DC1 according to some examples, the remaining lower metal lines, excluding the first metal line MT1, may be shifted inward from the boundary condition of the first decoupling capacitor cell DC1, thereby maintaining the capacitance capacity of the cell while allowing the lower metal lines to be routed only internally.

Referring back to FIG. 4, a discharge path for discharging plasma charges occurring in the first decoupling capacitor cell DC1 may be generated in the first I/O pad 310. The first I/O pad 310 may include a first junction region 311 formed on the substrate Sub, and the first junction region 311 may be physically connected to the fifth metal line MT5 through a first via VIA1. The first I/O pad 310 may include the fifth metal line MT5, the fourth metal line MT4, the third metal line MT3, and the second metal line MT2 apart from each other in the Z-axis direction, and the metal lines may be connected to each other in the third direction through vias VIA. The second metal line MT2 may be connected to the first metal line MT1 in the third direction through the vias VIA.

The first I/O pad 310 may form a first discharge path DCPATH1 by the first junction region 311. The first junction region 311 of the first I/O pad 310 may be a diode having an np junction of a p-type well and an n-type diffusion, or a diode having an np junction of an n-type well and a p-type diffusion. In some implementations, the first junction region 311 may be implemented in other manners.

As the first junction region 311 and the first metal line MT1 form the first discharge path DCPATH1, plasma charges or noise signals occurring in the first decoupling capacitor cell DC1 may be guided toward the first I/O pad 310. Due to this, charges occurring in the first decoupling capacitor cell DC1 may be prevented from being applied to the transistors inside the first decoupling capacitor cell DC1, thereby protecting transistors inside the first decoupling capacitor cell DC1 and preventing an analog circuit including the internal transistors from being deteriorated by micro noise. In addition, in some examples, because the first junction region 311 formed on the first I/O pad 310 is connected to the first metal line MT1, which is the top metal, thereby discharging, a new junction region is not added, so a new region is not added for discharging, which may be advantageous in terms of region.

Referring to the examples of FIGS. 3 to 5, because the first decoupling capacitor cell DC1 forms a first discharge path in the direction of the I/O pads, the interior of the first decoupling capacitor cell DC1 may not include a junction region, and all gates included in the first decoupling capacitor cell DC1 may be configured to be connected to metal lines.

In FIGS. 4 and 5, an example in which the metal layer includes a total of five layers is illustrated. In some implementations, the first decoupling capacitor cell DC1 may include N metal layers. N may be a natural number greater than or equal to 2.

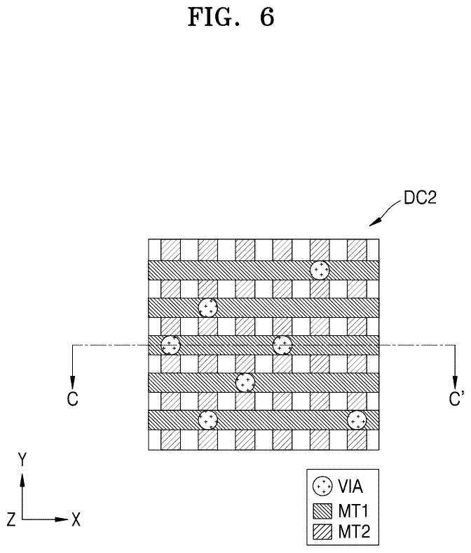

FIG. 6 is a plan view of the second decoupling capacitor cell DC2 according to some implementations.

Referring to FIG. 6, the second decoupling capacitor cell DC2 may include the plurality of first metal lines MT1 extending in the first direction and arranged apart from each other in the second direction, and the plurality of second metal lines MT2 extending in the second direction and arranged apart from each other in the first direction. In an example, the plurality of second metal lines MT2 may be arranged below the first metal lines MT1.

The plurality of first metal lines MT1 and the plurality of second metal lines MT2 formed in different layers may be physically connected through the vias VIA extending in the third direction. In some examples, the second decoupling capacitor cell DC2 may not be physically connected to the I/O pads. The structure and discharge path in the second decoupling capacitor cell DC2 are described in detail through cross-sectional views below.

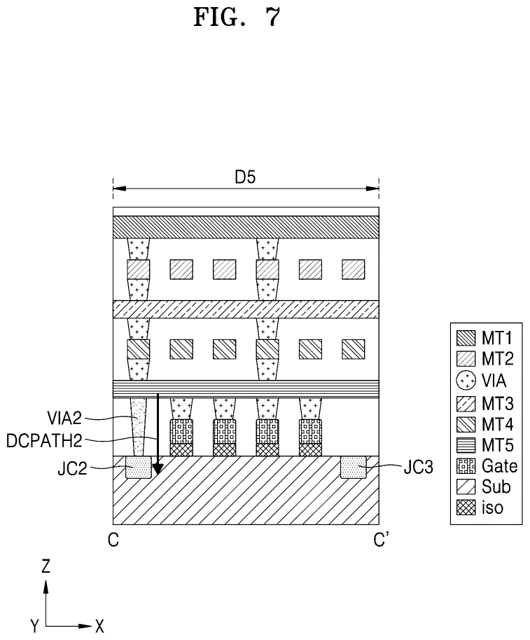

FIG. 7 is a cross-sectional view of each example of the second decoupling capacitor cell DC2 of FIG. 6 taken along line C-C′.

Referring to FIG. 7, the second decoupling capacitor cell DC2 may include the first metal line MT1, the third metal line MT3, and the fifth metal line MT5 extending in the first direction. The second decoupling capacitor cell DC2 may include the second metal line MT2 and the fourth metal line MT4 extending in the second direction, and the plurality of metal lines may be physically connected through the vias VIA extending vertically. In an example, an insulating material Iso may be connected between the plurality of gates Gate and the substrate Sub. Active regions that may be combined with the plurality of gates Gate to form a MOS capacitor may be formed on the substrate Sub, but are not shown in the cross-sectional views of FIGS. 7 to 9. In some examples, a plurality of MOS capacitors respectively corresponding to the plurality of gates Gate included in the second decoupling capacitor cell DC2 may be formed on the substrate Sub.

According to the example of FIG. 7, the substrate Sub of the second decoupling capacitor cell DC2 may include a second junction region JC2 and a third junction region JC3. The second junction region JC2 and the third junction region JC3 may be diodes having an np junction of a p-type well and an n-type diffusion or diodes having an np junction of an n-type well and a p-type diffusion. In some implementations, the second junction region JC2 and the third junction region JC3 may be implemented in other manners.

Referring to FIG. 7, the second junction region JC2 may be formed in the substrate Sub. The second junction region JC2 may be physically connected to the fifth metal line MT5, which is the bottom metal layer of the second decoupling capacitor cell DC2, through a second via VIA2. According to some implementations, the length of the plurality of metal lines included in the second decoupling capacitor cell DC2 may have a value equal to the length of the boundary of the second decoupling capacitor cell DC2.

According to some implementations, the lengths of the first metal line MT1, the third metal line MT3, and the fifth metal line MT5 included in the second decoupling capacitor cell DC2 in the first direction may be the same as the length D5 of the second decoupling capacitor cell DC2 in the first direction. The lengths of the second metal line MT2 and the fourth metal line MT4 included in the second decoupling capacitor cell DC2 in the second direction may be the same as the length of the second decoupling capacitor cell DC2 in the second direction. The plurality of metal lines included in the second decoupling capacitor cell DC2 may share metal lines with adjacent decoupling capacitor cells.

Because the second decoupling capacitor cell DC2 may have a structure of sharing metal lines with an adjacent decoupling capacitor cell and it is necessary to discharge plasma charges occurring in the corresponding capacitor cell inside the decoupling capacitor cell, the second decoupling capacitor cell DC2 may discharge plasma charges occurring in the second decoupling capacitor cell DC2 through the second junction region JC2. This allows the formation of a second discharge path DCPATH2. In some implementations, a discharge path may be formed inside the second decoupling capacitor cell DC2 through the fifth metal line MT5, which is a bottom metal line, and the second junction region JC2.

In some examples, the second decoupling capacitor cell DC2 may include a plurality of junction regions JC2 and JC3, at least some of which may be connected to the bottom metal line. In some examples, the bottom metal line may refer to a metal line located at the closest height to the gate in the third direction, and in FIGS. 7 to 9, the bottom metal line may be the fifth metal line MT5. In some implementations, the second decoupling capacitor cell DC2 may include two or more second junction regions and at least one of the two or more second junction regions may be configured to be physically connected to a metal line that is on top of the plurality of gates.

According to the example of FIG. 7, the second decoupling capacitor cell DC2 may include the plurality of junction regions JC2 and JC3, and among these, the second junction region JC2 may be physically connected to the fifth metal line MT5 through the second via VIA2 to form the second discharge path DCPATH2.

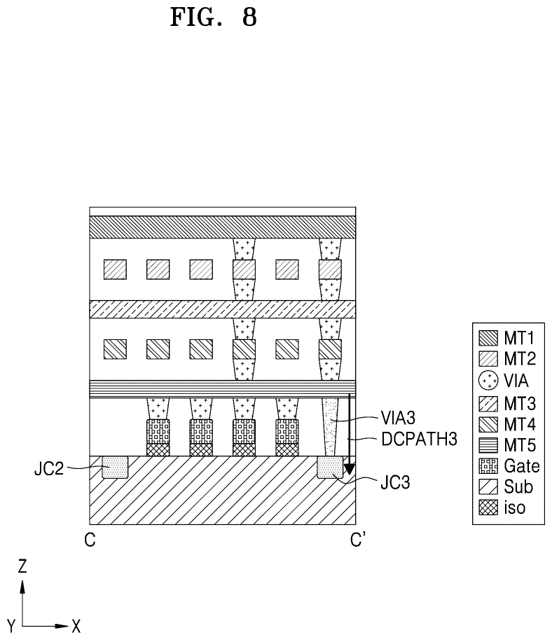

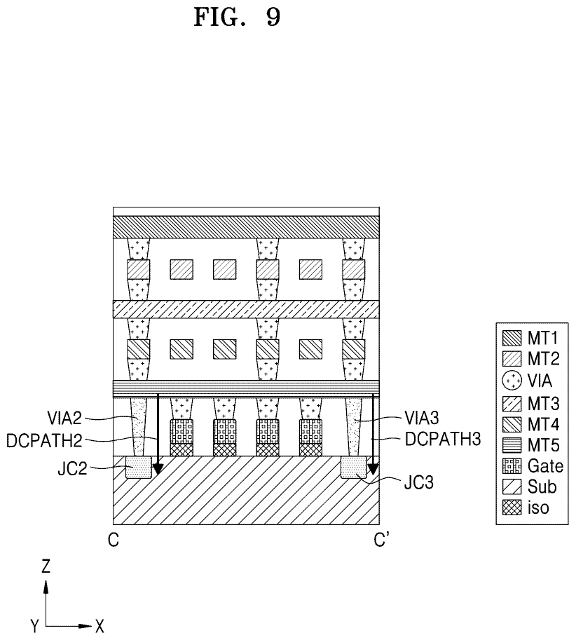

FIGS. 8 and 9 are other examples of cross-sectional views of the second decoupling capacitor cell DC2.

According to some implementations, the cross-sectional views of FIGS. 8 and 9 are cross-sectional views of the second decoupling capacitor cell DC2 of FIG. 6, taken in the direction extending along the X-axis. In some examples, the positions of the vias illustrated in FIGS. 8 and 9 do not correspond to a layout structure of the vias included in the second decoupling capacitor cell DC2 of FIG. 6. However, this is illustrated by omitting the via structure of the second decoupling capacitor cell DC2 for convenience of description, and the second decoupling capacitor cell DC2 configured to correspond to the positions of the vias illustrated in FIGS. 8 and 9 may be disclosed.

According to some implementations, referring to the example of FIG. 8, the second decoupling capacitor cell DC2 may include the plurality of junction regions JC2 and JC3, of which the third junction region JC3 may be physically connected to the fifth metal line MT5 through a third via VIA3. Through this, a third discharge path DCPATH3 may be formed.

According to some implementations, referring to the example of FIG. 9, the second decoupling capacitor cell DC2 may include the plurality of junction regions JC2 and JC3, of which the second junction region JC2 may be physically connected to the fifth metal line MT5 through the second via VIA2 and the third junction region JC3 may be physically connected to the fifth metal line MT5 through the third via VIA3. Through this, the second discharge path DCPATH2 and the third discharge path DCPATH3 may be formed.

Referring to the examples of FIGS. 7 to 9, the second decoupling capacitor cell DC2 may include a junction region capable of forming one or more discharge paths in the substrate Sub inside the cell. By connecting the junction region to the bottom metal line through the via, one or more discharge paths may be formed, through which plasma charges occurring inside the second decoupling capacitor cell DC2 may be discharged inside the cell.

According to some implementations, the second junction region JC2 and the third junction region JC3 illustrated in FIGS. 7 to 9 may correspond to a guard ring structure.

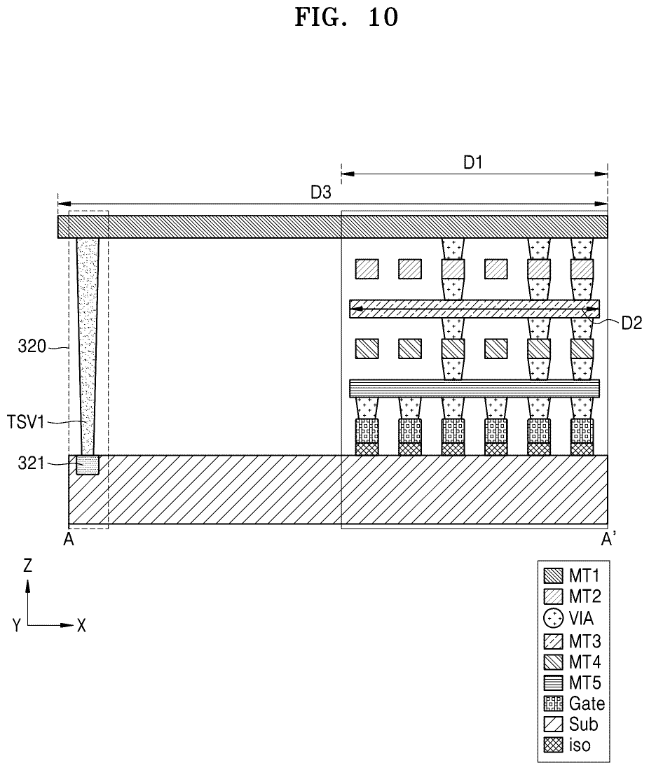

FIG. 10 is another example of a cross-sectional view of a first decoupling capacitor cell according to some implementations.

In the description of FIG. 10, descriptions of the components as those described above with reference to FIG. 4 are omitted.

Referring to FIG. 10, the first metal line MT1 of the first decoupling capacitor cell may extend in the first direction to the I/O pad 320. In some examples, the I/O pad 320 may include a first junction region 321 formed in the substrate Sub. The first junction region 321 may be physically connected to the first metal line MT1 through a through-silicon via TSV1. That is, various structures that may connect the first junction region 321 to the first metal line MT1 in the third direction may be provided.

According to some implementations, the first decoupling capacitor cell may be applied when the influence of capacitance is relatively insignificant and an IR drop purpose is strong, and the second decoupling capacitor cell may be applied to quickly handle discharge when the capacitor is used as an RC circuit in an analog circuit.

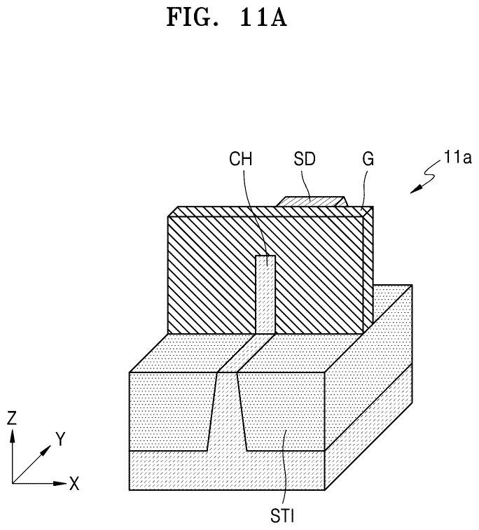

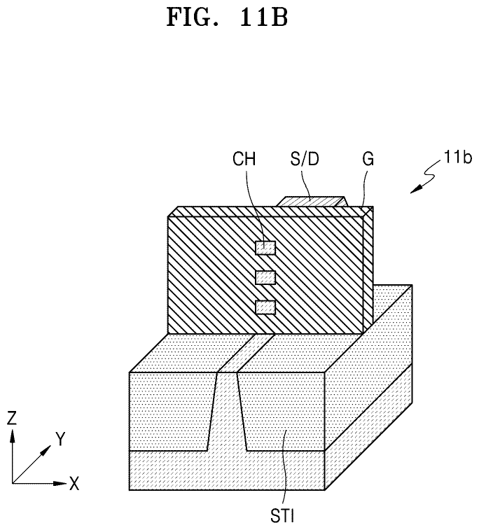

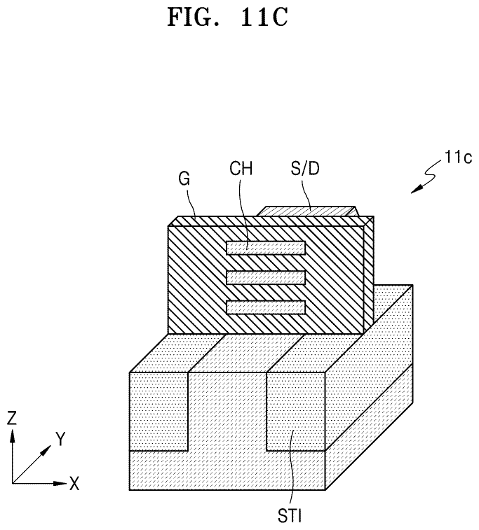

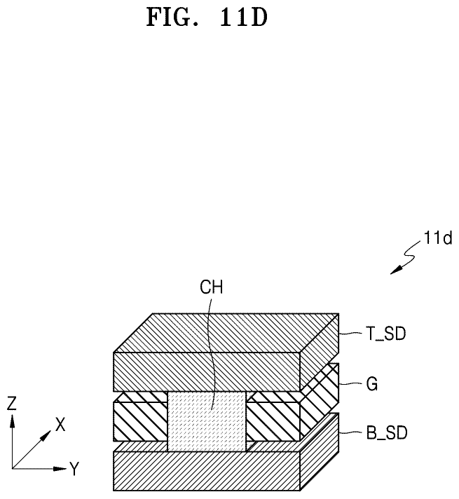

FIGS. 11A to 11D are diagrams illustrating examples of components that may be included in an integrated circuit according to examples.

For example, FIG. 11A shows a FinFET 11a, FIG. 11B shows a gate-all-around field effect transistor (GAAFET) 11b, FIG. 11C shows a multi-bridge channel field effect transistor (MBCFET) 11c, and FIG. 11D shows a vertical field effect transistor (VFET) 11d. For convenience of illustration, FIGS. 11A to 11C illustrate a state in which one of two source/drain regions is removed, and FIG. 11D illustrates a cross-section of the VFET 11d taken along a plane parallel to a plane of the Y-axis and the Z-axis and passing through a channel CH of the VFET 11d.

Referring to FIG. 11A, the FinFET 11a may be formed by a fin-shaped active pattern extending in the Y-axis direction between shallow trench isolations (STI) and a gate electrode G extending in the X-axis direction. Source/drain regions SD may be formed on opposite sides of the gate electrode G, and thus, the source may be apart from the drain in the Y-axis direction. An insulating film may be formed between the channel CH and the gate electrode G. In some implementations, the FinFET may be formed by a plurality of active patterns and the gate electrode G apart from each other in the X-axis direction and may have an expanded channel.

Referring to FIG. 11B, the GAAFET 11b may be formed by active patterns, i.e. nanowires, that are apart from each other in the Z-axis direction and extending in the Y-axis direction and the gate electrode G that extends in the X-axis direction. Source/drain regions SD may be formed on opposite sides of the gate electrode G, and thus, the source may be apart from the drain in the Y-axis direction. An insulating film may be formed between the channel CH and the gate electrode G. The number of nanowires included in the GAAFET 11b may not be limited to that shown in FIG. 11B.

Referring to FIG. 11C, the MBCFET 11c may be formed by active patterns, i.e. nanosheets, that are apart from each other in the Z-axis direction and extending in the Y-axis direction and the gate electrode G that extends in the X-axis direction. Source/drain regions SD may be formed on opposite sides of the gate electrode G, and thus, the source may be apart from the drain in the Y-axis direction. An insulating film may be formed between the channel CH and the gate electrode G. The number of nanosheets included in the MBCFET is not limited to that shown in FIG. 11C.

Referring to FIG. 11D, the VFET 11d may include a top source/drain region T_SD and a bottom source/drain region B_SD apart from each other in the Z-axis direction with a channel CH therebetween. The VFET 11d may include the gate electrode G surrounding the periphery of the channel CH between the top source/drain region T_SD and the bottom source/drain region B_SD. An insulating film may be formed between the channel CH and the gate electrode G.

The devices included in the integrated circuit according to some examples may not be limited to the examples of devices illustrated in FIGS. 11A to 11D. For example, the integrated circuit may include a ForkFET in which an N-type transistor and a P-type transistor are closer as the nanosheets for the P-type transistor and the nanosheets for the N-type transistor are separated by a dielectric wall. In addition, the integrated circuit may include a bipolar junction transistor, as well as FETs, such as a complementary field effect transistor (CFET), a negative capacitance field effect transistor (NCFET), and a carbon nanotube (CNT) FET.

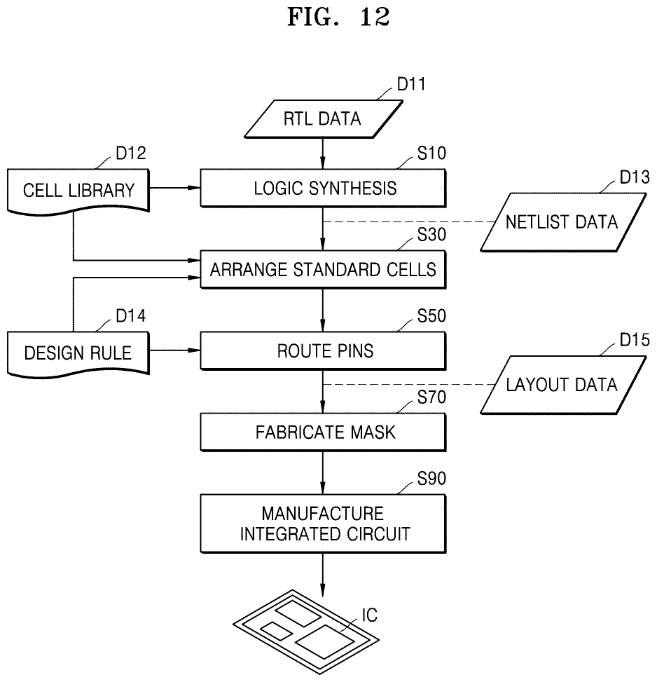

FIG. 12 is a flowchart illustrating a method of manufacturing an integrated circuit, according to some implementations.

Referring to FIG. 12, the method according to the present implementation may be a method of manufacturing an integrated circuit (IC) including standard cells and decoupling capacitor cells and may include a plurality of operations S10, S30, S50, S70, and S90. A cell library (or a standard cell library) D12 may include information on standard cells, such as information on their function, characteristics, layout, etc. In some implementations, the cell library D12 may define tap cells, filler cells, and dummy cells, as well as functional cells that generate output signals from input signals. In some implementations, the cell library D12 may define a plurality of bit cells. Design rules D14 may include requirements that the layout of an integrated circuit IC should adhere to. For example, design rule D14 may include requirements for spacing between patterns on the same layer, the minimum width of patterns, a routing direction in the interconnection layer, etc.

In operation S10, a logic synthesis operation for generating netlist data D13 from RTL data D11 may be performed. For example, a semiconductor design tool (e.g., a logic synthesis tool) may perform logic synthesis by referencing the cell library D12 from RTL data D11 written in VHSIC hardware description language (VHDL) and hardware description language (HDL), such as Verilog, and may generate netlist data D13 including a bitstream or netlist. The netlist data D13 may correspond to input of place and routing described below.

In operation S30, standard cells may be placed. For example, a semiconductor design tool (e.g., a P&R tool) may place standard cells used in the netlist data D13 by referencing the cell library D12. In addition, the bit cells may be arranged. For example, a semiconductor design tool may place bit cells alongside standard cells.

In operation S50, pins of standard cells may be routed. For example, a semiconductor design tool may generate interconnections that electrically connect output pins to input pins of placed standard cells and generate layout data D15 defining the placed standard cells and the generated interconnections. Interconnection may include via of a via layer and/or patterns of interconnection layers. The interconnection layers may include a front interconnection layer disposed on top of the front surface of the substrate and a rear interconnection layer disposed on a rear surface of the substrate. The layout data D15 may have a format, such as GDSII, and may include geometric information of cells and interconnections. Semiconductor design tools may refer to design rule D14 while routing the pins of cells. Layout data D15 may correspond to placement and output of routing. Operation S50 alone or operations S30 and S50 collectively may be referred to as a method of designing an integrated circuit.

In some implementations, as illustrated in FIGS. 1 to 10, the integrated circuit may include a first decoupling capacitor cell and a second decoupling capacitor cell. In some examples, the first decoupling capacitor cell may be connected to the junction region included in the I/O pad through the top metal to form the first discharge path. In some examples, the second decoupling capacitor may be connected to the junction region formed on the internal substrate of the second decoupling capacitor cell through the internal bottom metal line to form the second discharge path. Through this, plasma charges formed in the decoupling capacitor cell may be effectively discharged, thereby increasing the stability of the device.

In operation S70, an operation of fabricating a mask may be performed. For example, optical proximity correction (OPC) to correct distortion phenomena, such as refraction caused by the characteristics of light in photolithography, may be applied to layout data D15. Patterns on a mask may be defined to form patterns arranged in a plurality of layers based on data to which OPC is applied, and at least one mask (or photomask) may be manufactured to form the patterns of each of the layers. In some implementations, the layout of the integrated circuit IC may be limitedly modified in operation S70, and the limited modification of the integrated circuit IC in operation S70 may be referred to as design polishing as post-processing to optimize the structure of the integrated circuit IC.

In operation S90, an operation of manufacturing an integrated circuit IC may be performed. For example, an integrated circuit IC may be manufactured by patterning a plurality of layers using at least one mask manufactured in operation S70. Front-end-of-line (FEOL) may include, for example, operations of planarizing a wafer, cleaning the wafer, forming a trench, forming a well, forming a gate line, and forming a source and a drain. By means of FEOL, individual components, such as transistors, capacitors, resistors, etc., may be formed on the substrate. In addition, back-end-of-line (BEOL) may include, for example, operations of silicidating gate, source, and drain regions, adding a dielectric, planarizing, forming holes, adding a metal layer, forming a via, forming a passivation layer, etc. By BEOL, individual components, such as transistors, capacitors, resistors, etc., may be interconnected. In some implementations, a middle-of-line (MOL) may be performed between the FEOL and BEOL, and contacts may be formed on individual elements. Next, the integrated circuit IC may be packaged into a semiconductor package and used as a component in a variety of applications.

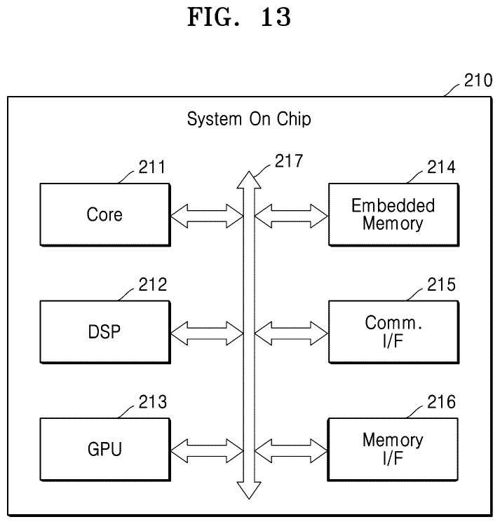

FIG. 13 is a block diagram illustrating a system-on-chip (SoC) 210 according to some implementations.

Referring to FIG. 13, the SoC 210 may refer to an integrated circuit that integrates components of a computing system or other electronic systems. For example, as an example of the SoC 210, an application processor (AP) may include a processor and components for other functions. The SoC 210 may include a core 211, a digital signal processor (DSP) 212, a graphics processing unit (GPU) 213, a built-in memory 214, a communication interface 215, and a memory interface 216. Components of the SoC 210 may communicate with each other through a bus 217.

The core 211 may process commands and control the operation of components included in the SoC 210. For example, the core 211 may drive an operating system and execute applications on the operating system by processing a series of commands. The DSP 212 may generate useful data by processing a digital signal, for example, a digital signal provided from the communication interface 215. The GPU 213 may generate data for an image output on a display device from image data provided from the built-in memory 214 or the memory interface 216 or may encode the image data. In some implementations, the integrated circuit described above with reference to the drawings may be included in the core 211, the DSP 212, the GPU 213 and/or the built-in memory 214.

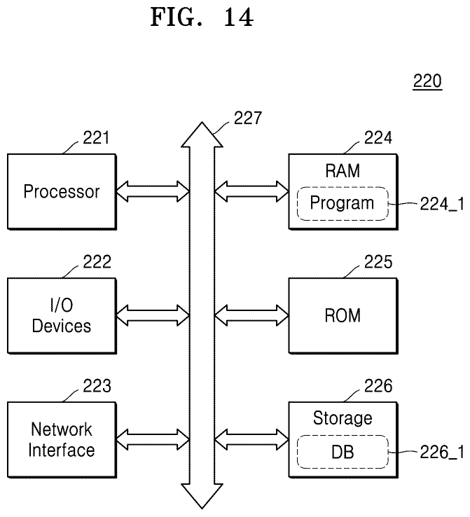

FIG. 14 is a block diagram illustrating a computing system 220 including a memory storing a program according to some implementations.

Referring to FIG. 14, a method of designing an integrated circuit according to some implementations, for example, at least some of the operations of the flowchart described above, may be performed in the computing system (or a computer) 220. The computing system 220 may include a processor 221, I/O devices 222, a network interface 223, random access memory (RAM) 224, read only memory (ROM) 225, and a storage 226. The processor 221, the I/O devices 222, the network interface 223, the RAM 224, the ROM 225, and the storage 226 may be connected to a bus 227 and communicate with each other through the bus 227.

The processor 221 may access memory, i.e., RAM 224 or ROM 225, through the bus 227 and execute instructions stored in the RAM 224 or the ROM 225. The RAM 224 may store a program 224_1 or at least a portion thereof for a method of designing an integrated circuit according to some implementations, and the program 224_1 may cause the processor 221 to perform at least some of the operations included in the method of designing an integrated circuit, for example, the methods of FIG. 12. That is, the program 224_1 may include a plurality of instructions executable by the processor 221, and the instructions included in the program 224_1 may cause the processor 221 to perform at least some of the operations included in the flowcharts described above.

The storage 226 may store the program 224_1 according to some implementations. In addition, the storage 226 may store a database 226_1, and the database 226_1 may include information necessary for designing an integrated circuit, such as information on designed blocks, the cell library D12 of FIG. 12, and/or design rule D14. The storage 226 may store data to be processed by the processor 221 or data processed by the processor 221. For example, the storage 226 may store RTL data D11, netlist data D13 and/or layout data D15 of FIG. 12.

While the inventive concept has been particularly shown and described with reference to implementations thereof, it will be understood that various changes in form and details may be made therein without departing from the spirit and scope of the following claims.

What is claimed is:

1. An integrated circuit comprising:
a first decoupling capacitor cell having a first discharge path that guides discharge of first charged particles; and
a second decoupling capacitor cell having a second discharge path that guides discharge of second charged particles,
wherein the first discharge path is in an external region of the first decoupling capacitor cell, and
wherein the second discharge path is in an internal region of the second decoupling capacitor cell.

2. The integrated circuit of claim 1, wherein the first decoupling capacitor cell comprises a plurality of metal lines,
wherein the plurality of metal lines comprise a plurality of groups of metal lines that are stacked in successive layers,
wherein each metal line of the plurality of metal lines has an elongation direction,
wherein the elongation direction alternates between a first direction and a second direction from one group of metal lines to the next group of metal lines,
wherein the plurality of metal lines comprise a top metal line and a plurality of lower metal lines below the top metal line,
wherein a length of a first lower metal line of the plurality of lower metal lines that extends in the first direction is different from a length of the first decoupling capacitor cell in the first direction, and
wherein a length of a second lower metal line of the plurality of lower metal lines that extends in the second direction is different from a length of the first decoupling capacitor cell in the second direction.

3. The integrated circuit of claim 2, wherein the length of the first lower metal line in the first direction is less than the length of the first decoupling capacitor cell in the first direction, and
wherein the length of the second lower metal line in the second direction is less than the length of the first decoupling capacitor cell in the second direction.

4. The integrated circuit of claim 2, comprising:
an input/output (I/O) pad configured to transmit and receive signals to and from the integrated circuit,
wherein the top metal line extends toward an upper region of the I/O pad.

5. The integrated circuit of claim 4, wherein the I/O pad is physically connected to the top metal line.

6. The integrated circuit of claim 5, wherein the I/O pad comprises a first junction region formed in a substrate.

7. The integrated circuit of claim 6, wherein the I/O pad comprises a via that connects the first junction region to the top metal line in a third direction.

8. The integrated circuit of claim 2, wherein the first decoupling capacitor cell comprises a plurality of metal-oxide-semiconductor (MOS) capacitor devices, and
wherein the plurality of MOS capacitor devices comprise a plurality of gates that are physically connected to the plurality of lower metal lines.

9. The integrated circuit of claim 1, wherein the second decoupling capacitor cell comprises:
a substrate;
a plurality of gates; and
a second junction region formed on the substrate.

10. The integrated circuit of claim 9, wherein the second junction region comprises two or more second junction regions, and
wherein at least one of the two or more second junction regions is physically connected to a metal line that is on top of the plurality of gates.

11. The integrated circuit of claim 10, wherein the metal line is a bottom metal line that is closest to the plurality of gates in a third direction.

12. The integrated circuit of claim 1, wherein a size of the first decoupling capacitor cell is equal to a size of the second decoupling capacitor cell.

13. An integrated circuit comprising:
a plurality of cell arrays,
wherein the plurality of cell arrays comprise
a first decoupling capacitor cell array comprising a plurality of first decoupling capacitor cells, and
a second decoupling capacitor cell array comprising a plurality of second decoupling capacitor cells,
wherein each first decoupling capacitor cell of the plurality of first decoupling capacitor cells comprises a plurality of top metal lines forming a first path that guides discharge of charged particles, and
wherein each second decoupling capacitor cell of the plurality of second decoupling capacitor cells comprises a second junction region that forms a second path that guides discharge of charged particles.

14. The integrated circuit of claim 13, wherein the integrated circuit comprises an input/output (I/O) pad physically connected to the plurality of top metal lines, and
wherein the I/O pad comprises a first junction region that forms at least a portion of the first path.

15. The integrated circuit of claim 14, wherein each first decoupling capacitor cell of the plurality of first decoupling capacitor cells does not include a junction region.

16. The integrated circuit of claim 13, wherein each second decoupling capacitor cell of the plurality of second decoupling capacitor cells comprises a plurality of second junction regions, and
wherein at least one of the plurality of second junction regions connected, in a third direction, to a metal line included in each of the plurality of second decoupling capacitor cells.

17. The integrated circuit of claim 16, wherein the metal line is a bottom metal line that is closest to a substrate in each second decoupling capacitor cell of the plurality of second decoupling capacitor cells.

18. An integrated circuit comprising:
a plurality of cell arrays; and
an input/output (I/O) pad configured to transmit and receive signals to and from the plurality of cell arrays,
wherein the I/O pad includes a first discharge path that guides discharge of charged particles, including plasma charged particles formed by the plurality of cell arrays.

19. The integrated circuit of claim 18, wherein the first discharge path is connected through a top metal line among a plurality of metal lines included in the plurality of cell arrays.

20. The integrated circuit of claim 18, wherein the plurality of cell arrays form a second discharge path that guides discharge of charged particles, including plasma charged particles that are formed by the plurality of cell arrays.
